(19) United States
(12) Patent Application Publication
(10) Pub. No.: US 2014/0085833 A1
(43) Pub. Date: Mar. 27, 2014

(54) CHIP PACKAGING SUBSTRATE, METHOD FOR MANUFACTURING SAME, AND CHIP PACKAGING STRUCTURE HAVING SAME

(71) Applicant: Zhen Ding Technology Co., Ltd., Tayuan (TW)

(72) Inventors: SHIH-PING HSU, Taoyuan (TW); E-TUNG CHOU, Taoyuan (TW); CHIH-JEN HSIAO, Taoyuan (TW)

(73) Assignee: ZHEN DING TECHNOLOGY CO., LTD., Tayuan (TW)

(21) Appl. No.: 14/029,735

(22) Filed: Sep. 17, 2013

(30) Foreign Application Priority Data
Sep. 25, 2012 (CN) 2012103602634

(51) Int. Cl. H05K 1/18; H05K 1/00; H05K 3/42; H05K 3/46; H05K 3/28

(52) U.S. Cl. CPC H05K 1/181; H05K 3/4652; H05K 3/281; H05K 3/421; H05K 1/00
USPC 361/728; 29/850; 174/251

(57) ABSTRACT

A chip packaging substrate includes a dielectric layer, a first inner wiring layer embedded in the dielectric layer, an outer wiring layer, and many conductive connection points. The outer wiring layer is formed at one side of the dielectric layer, and is electrically connected to the first inner wiring layer through many first conductive vias in the dielectric layer. The conductive connection points are formed at the other side of the dielectric layer, and are electrically connected to the first inner wiring layer through many second conductive vias in the dielectric layer.

### BACKGROUND

1. Technical Field

The present disclosure generally relates to printed circuit boards, and particularly to a chip packaging substrate, a method for manufacturing the chip packaging substrate, and a chip packaging structure having the chip packaging substrate.

2. Description of Related Art

Chip packaging substrates supply electrical connections, protection, and support to a chip. The goal of manufacturing chip packaging substrates is to make them smaller and smaller, while improving electrical connections within the chip packaging substrates.

A multilayer chip packaging substrate includes a core and two wiring structures constructed on two opposite sides of the core. However, the multilayer chip packaging substrate becomes thick due to the presence of the core.

What is needed, therefore, is a chip packaging substrate, a method for manufacturing the chip packaging substrate, and a chip packaging structure having the chip packaging substrate to overcome the above-described problems.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded perspective view of a first base, a second base, a first copper sheet, a second copper sheet, and a connection sheet according to an exemplary embodiment.

FIG. 2 shows a supporting substrate obtained by stacking and laminating the first base, the first copper sheet, the connection sheet, the second copper sheet, and the second base of FIG. 1 in that order.

FIG. 3 shows a lamination of a second copper foil, a second adhesive sheet, a first copper foil, a first adhesive sheet, the supporting substrate of FIG. 2, a third adhesive sheet, a third copper foil, a fourth adhesive sheet, and a fourth copper foil.

FIG. 4 shows a first photoresist pattern formed on the second copper foil and a second photoresist pattern formed on the fourth copper foil of FIG. 3.

FIG. 5 shows a first inner wiring layer converted by the second copper foil and a second inner wiring layer converted by the fourth copper foil of FIG. 4.

FIG. 6 shows a lamination of a fifth adhesive sheet, a fifth copper foil, the first inner layer, the second inner layer of FIG. 5, a sixth adhesive sheet, and a sixth copper foil to obtain a multilayer substrate.

FIG. 7 shows a first substrate and a second substrate obtained by cutting the multilayer substrate of FIG. 6.

FIG. 8 shows a plurality of first blind vias and second blind vias defined in the first substrate of FIG. 7.

FIG. 9 shows the first substrate of FIG. 8 after panel plating.

FIG. 10 shows an outer wiring layer and a plurality of conductive connection points respectively formed at two opposite sides of the first substrate of FIG. 9.

FIG. 11 shows a first solder mask formed on the outer wiring layer of FIG. 10 to obtain a chip packaging substrate.

FIG. 12 shows a chip packaged on the chip packaging substrate of FIG. 11.

FIG. 13 shows a packaging material formed on the chip of FIG. 12.

FIG. 14 shows a plurality of solder balls formed on the conductive connection points of FIG. 13 to obtain a chip packaging structure.

### DETAILED DESCRIPTION

A method for manufacturing a chip packaging substrate includes the following steps.

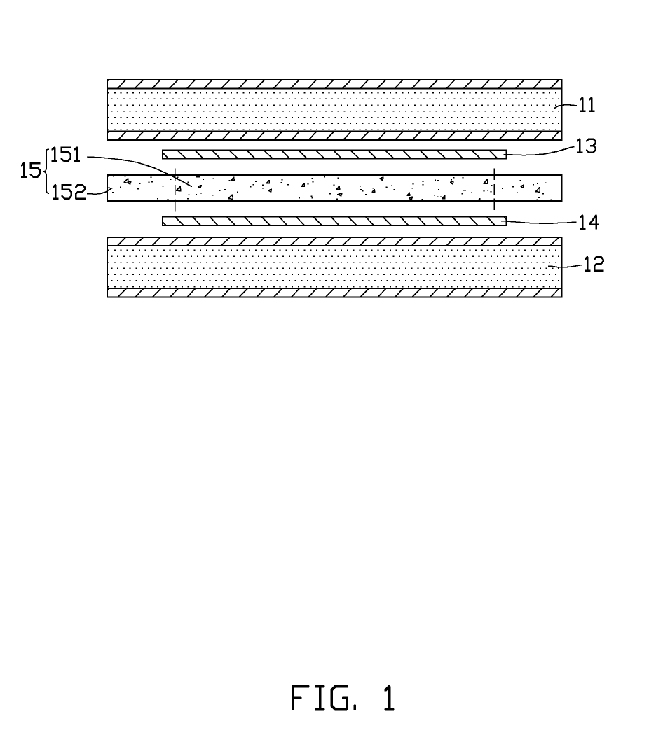

FIG. 1 shows step 1, in which a first base 11, a second base 12, a first copper sheet 13, a second copper sheet 14, and a connection sheet 15 are provided. In the present embodiment, the first base 11 and the second base 12 are double-sided copper-clad laminates. That is, the first base 11 and the second base 12 each includes two copper layers and an insulating layer sandwiched between the two copper layers.

A shape of the first base 11, a shape of the second base 12, and a shape of the connection sheet 15 are substantially identical to each other. A size of the first base 11, a size of the second base 12, and a size of the connection sheet 15 are substantially identical to each other. A shape of the first copper sheet 13 is substantially identical to a shape of the second copper sheet 14, and the shape of the first copper sheet 13 is identical to the shape of the first base 12. A size of the first copper sheet 13 is identical to a size of the second copper sheet 14, and the size of the first copper sheet 13 is smaller than the size of the first base 11. The connection sheet 15 includes a central area 151 and a peripheral area 152 surrounding the central area 151. A shape of the central area 151 is identical to a shape of the first copper sheet 14, and the size of the first copper sheet 14 is slightly larger than the size of the central area 151.

In the present embodiment, each of the insulating layers of the first base 11 and the second base 12 is an FR4 epoxy glass cloth pre-preg.

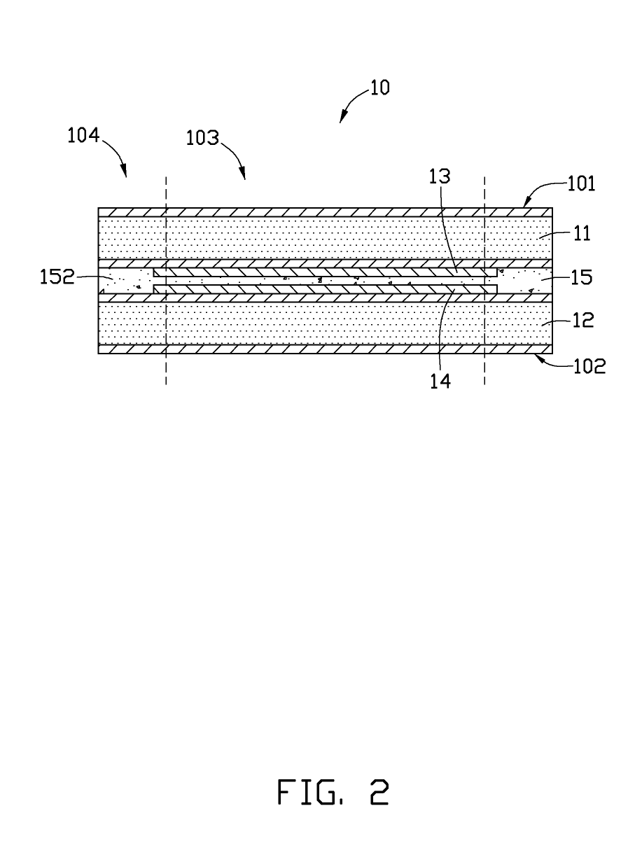

FIG. 2 shows step 2, in which the first base 11, the first copper sheet 13, the connection sheet 15, the second copper sheet 14, and the second base 12 are stacked in the described order and are laminated to obtain a supporting substrate 10. The supporting substrate 10 includes a first surface 101 and a second surface 102 facing away from the first surface 101. The first surface 101 is a surface of the copper layer of the first base 11 further away from the connection sheet 15. The second surface 102 is a surface of the copper layer of the second base 12 further away from the connection sheet 15. The supporting substrate 10 includes a product area 103 and a non-product area 104 surrounding the product area 103. A cross-section of the product area 103 is smaller than a cross-section of the first copper sheet 13. That is, an orthographic projection of the product area 103 on the first base 11 is located in an orthographic projection of the first copper sheet 13 on the first base 11.

In alternative embodiments, the first copper sheet 13 and the second copper sheet 14 may be omitted, so that the first base 11 is connected to the second base 12 by the connection sheet 15. In such a case, the connection sheet 15 may be a peelable type adhesive. In alternative embodiments, the supporting substrate 10 may be made of polyimide, glass-fibre laminate, or metal (e.g. copper), for example.

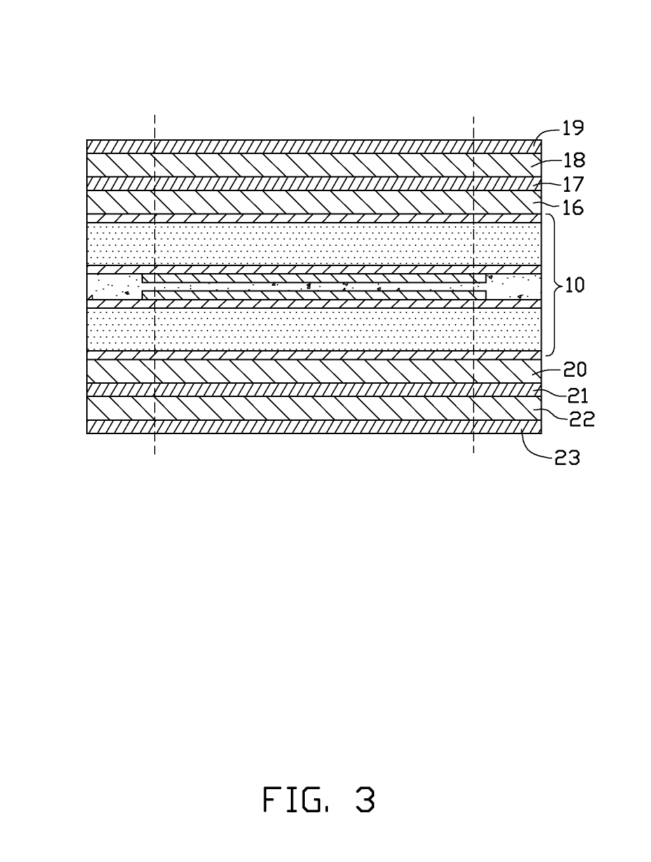

FIG. 3 shows step 3, in which a first adhesive sheet 16, a first copper foil 17, a second adhesive sheet 18, a second copper foil 19, a third adhesive sheet 20, a third copper foil 21, a fourth adhesive sheet 22, and a fourth copper foil 23 are provided. Then, the second copper foil 19, the second adhesive sheet 18, the first copper foil 17, the first adhesive sheet 16, the supporting substrate 10, the third adhesive sheet 20, the third copper foil 21, the fourth adhesive sheet 22, and the fourth copper foil 23 are stacked and laminated together in that order.

The first adhesive sheet 16, the second adhesive sheet 18, the third adhesive sheet 20, and the fourth adhesive sheet 22 are each an FR4 epoxy glass cloth pre-preg. It is understood that step 2 and step 3 may be simultaneously processed, so that there is no need to laminate twice.

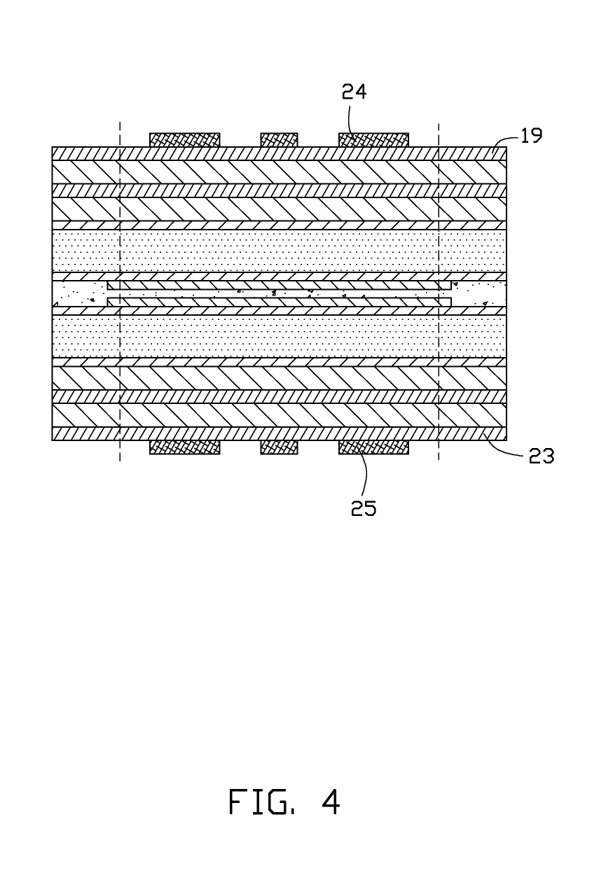

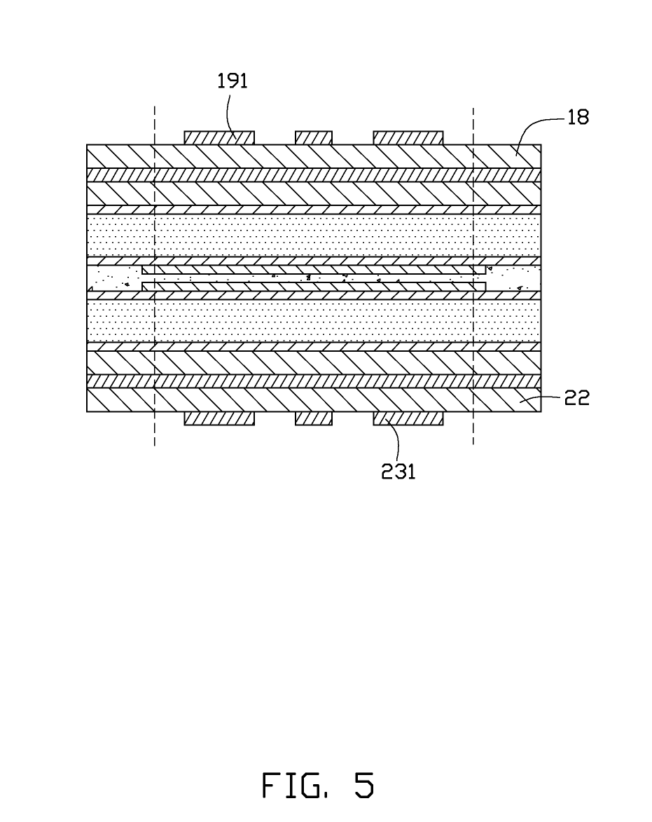

FIGS. 4 and 5 show step 4, in that the second copper foil 19 is patterned into a first inner wiring layer 191, and the fourth copper foil 23 is patterned into a second inner wiring layer 231.

The first and second inner wiring layers 191 and 231 may be formed in the following steps. First, referring to FIG. 4, a first photoresist pattern 24 is formed on the second copper foil 19, and a second photoresist pattern 25 is formed on the fourth copper foil 23. Then, a portion of the second copper foil 19 exposed by the first photoresist pattern 24 is etched by a copper etching solution, thereby forming the first inner wiring layer 191; a portion of the fourth copper foil 23 is etched by the copper etching solution, thereby forming the second inner wiring layer 231. Finally, the first photoresist pattern 24 and the second photoresisst pattern 25 are removed from the supporting substrate 10.

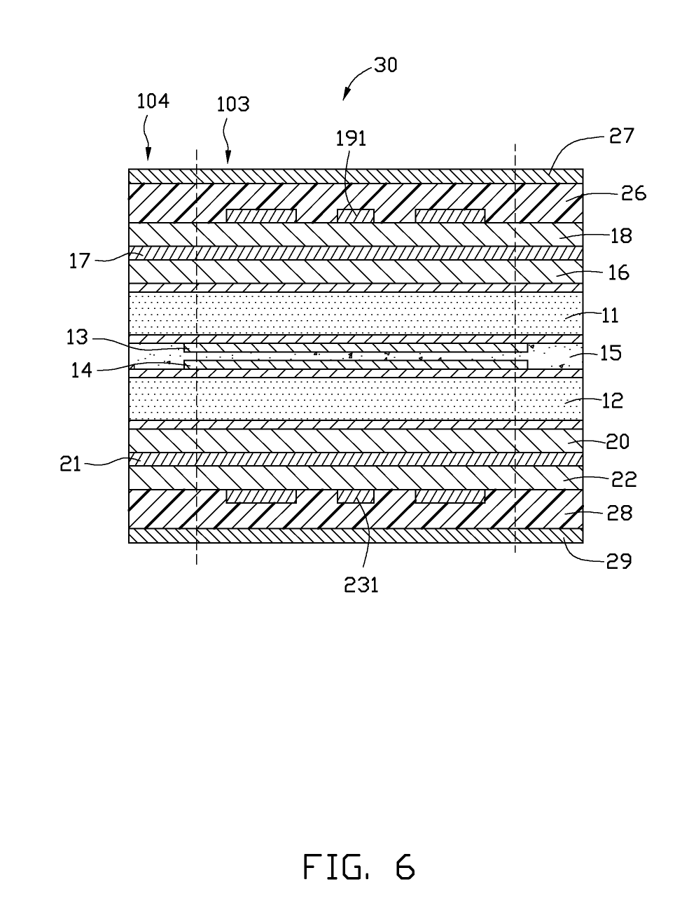

FIG. 6 shows step 5, in which a fifth adhesive sheet 26 and a fifth copper foil 27 are laminated onto the first inner layer 191, such that the fifth adhesive sheet 26 is sandwiched between the fifth copper foil and the first inner layer 191; a sixth adhesive sheet 28 and a sixth copper foil 29 are laminated onto the second inner layer 231, such that the sixth adhesive sheet 28 is sandwiched between the sixth copper foil 29 and the second inner layer 231. A multilayer substrate 30 is thus obtained.

The fifth adhesive sheet 26 and the sixth adhesive sheet 28 are each an FR4 epoxy glass cloth pre-preg. The fifth adhesive sheet 26 totally covers the first inner wiring layer 191 and a surface of the second adhesive sheet 18 exposed from the first inner wiring layer 191. The sixth adhesive sheet 28 totally covers the second inner wiring layer 231 and a surface of the fourth adhesive sheet 22 exposed from the second inner wiring layer 231.

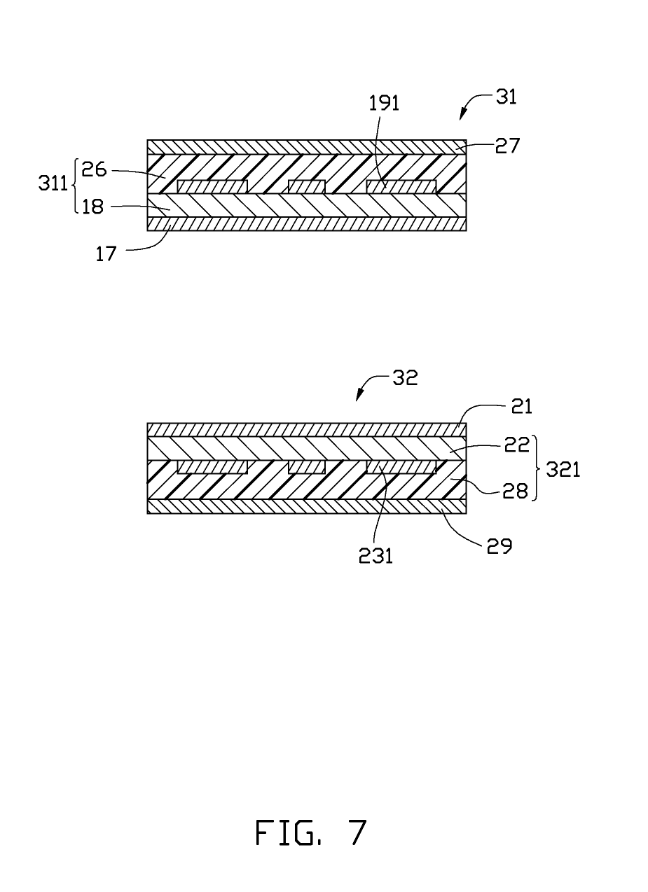

FIGS. 6 and 7 show step 6, in which the multilayer substrate 30 is cut along a boundary between the product area 103 and the non-product area 104 to remove the non-product area 104 from the product area 103; the first base 11, the first adhesive sheet 16, the second base 12, and the third adhesive sheet 20 are removed from the first copper foil 17 and the third copper foil 21, thereby obtaining a first substrate 31 and a second substrate 32 separated from the first substrate 31. The fifth adhesive sheet 26 and the second adhesive sheet 18 cooperatively form a dielectric layer 311 of the first substrate 31. The sixth adhesive sheet 28 and the fourth adhesive sheet 22 cooperatively constitute a dielectric layer 321 of the second substrate 32.

In the product area 103, the first copper sheet 13 is connected to the second copper sheet 14 via the connection sheet 15, and the first base 11 and the second base 12 are separated from the connection sheet 15. Thus, when the multilayer substrate 30 is cut along the boundary between the product area 103 and the non-product area 104, the first base 11 and the second base 12 are naturally separated from the connection sheet 15.

When there is no first copper sheet 13 and no second copper sheet 14 in the supporting substrate 10, the first base 11 is separated from the second base 12 by cutting the connection sheet 15, thereby obtaining the first substrate 31 and the second substrate 32. When there is no first copper sheet 13 and no second copper sheet 14 in the supporting substrate 10, and the connection sheet 15 is a peelable type adhesive, the first substrate 31 is separated from the second substrate 32 by peeling, thereby obtaining the first substrate 31 and the second substrate 32.

It is noted that, because the first substrate 31 is the substantially the same as the second substrate 32, a method for converting the first substrate 31 into a chip packaging substrate and a method for packaging a chip using the chip packaging substrate is substantially the same as that for the second substrate 32, so the embodiment only describes the method once for the first substrate 31 for simplicity.

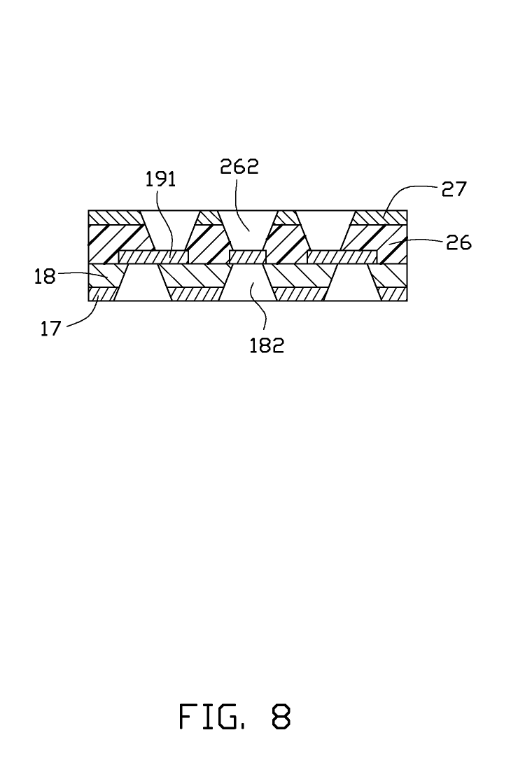

FIGS. 8 to 10 show step 7, in which a plurality of first conductive vias 33 is formed in the fifth copper foil 27 and the fifth adhesive sheet 26, and a plurality of second conductive vias 34 is formed in the first copper foil 17 and the second adhesive sheet 18. Then, an outer wiring layer 272 is formed on a side of the fifth copper foil 27, and a plurality of conductive connection points 180 is formed on a side of the first copper foil 17. The outer wiring layer 272 is electrically connected to the inner wiring layer 191 through the first conductive vias 33. The conductive connection points 180 are electrically connected to the inner wiring layer 191 through the second conductive vias 34.

The first conductive vias 33, the second conductive vias 34, the outer wiring layer 272, and the conductive connection points 180 may be formed by the following steps:

First, referring to FIG. 8, a plurality of first blind vias 262 is defined in the fifth copper foil 27 and the fifth adhesive sheet 26 by laser ablation, and a plurality of second blind vias 182 is defined in the first copper foil 17 and the second adhesive sheet 18. A part of one side of the inner wiring layer 191 is exposed by the first blind vias 262, and a part of the other side of the inner wiring layer 191 is exposed by the second blind vias 182.

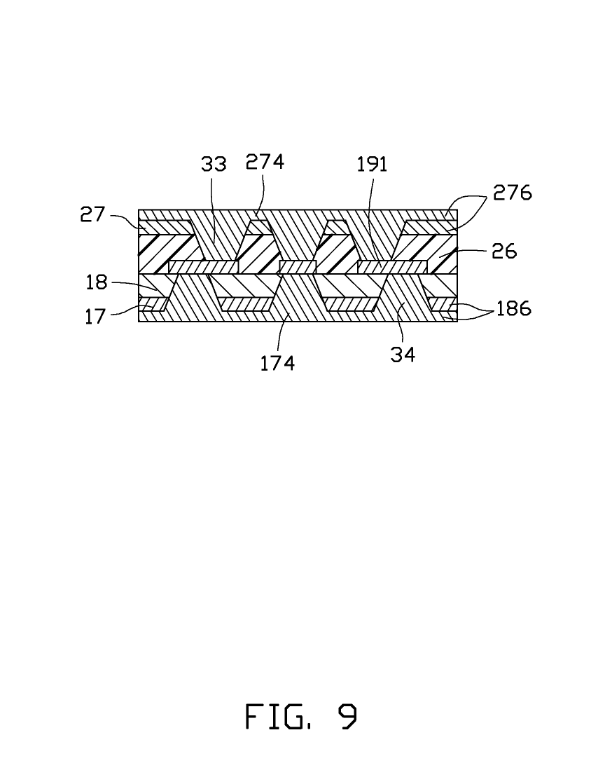

Second, referring also to FIG. 9, the first substrate 31 with the first blind vias 262 and the second blind vias 182 is panel plated to form a first plating copper layer 274 in the first blind vias 262 and on the fifth copper foil 27.

A second plating copper layer 174 is formed in the second blind vias 182 and on the first copper foil 17. The first plating copper layer 274 fully fills the first blind vias 262 and electrically connects the fifth copper foil 27 to the inner wiring layer 191. The first plating copper layer 274 and the fifth copper foil 27 cooperatively form a first conductive copper layer 276. The first plating copper layer 274 in each first blind via 262 forms the first conductive via 33. The second plating copper layer 174 fully fills the second blind vias 182, and electrically connects the first copper foil 17 to the inner wiring layer 191. The second plating copper layer 174 and the first copper foil 17 cooperatively form a second conductive copper layer 186. The second plating copper layer 174 in each second blind via 262 forms the second conductive via 34.

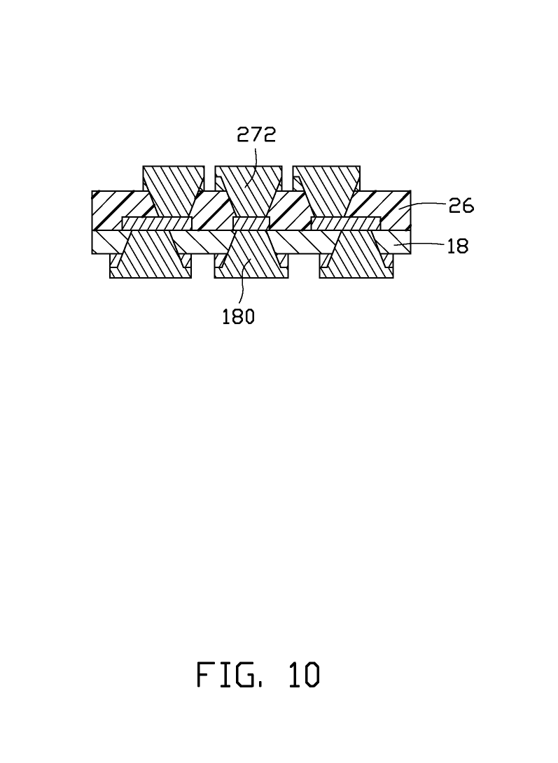

Finally, referring to FIG. 10, the first conductive copper layer 276 is patterned into the outer wiring layer 272, and the second conductive copper layer 186 is converted into the conductive connection points 180 by using an image transfer process and an etching process. In the present embodiment, the outer wiring layer 272 includes a plurality of wirings.

In alternative embodiments, the second conductive copper layer 186 may be patterned into the outer wiring layer, and the first conductive copper layer 276 may be converted into the conductive connection points.

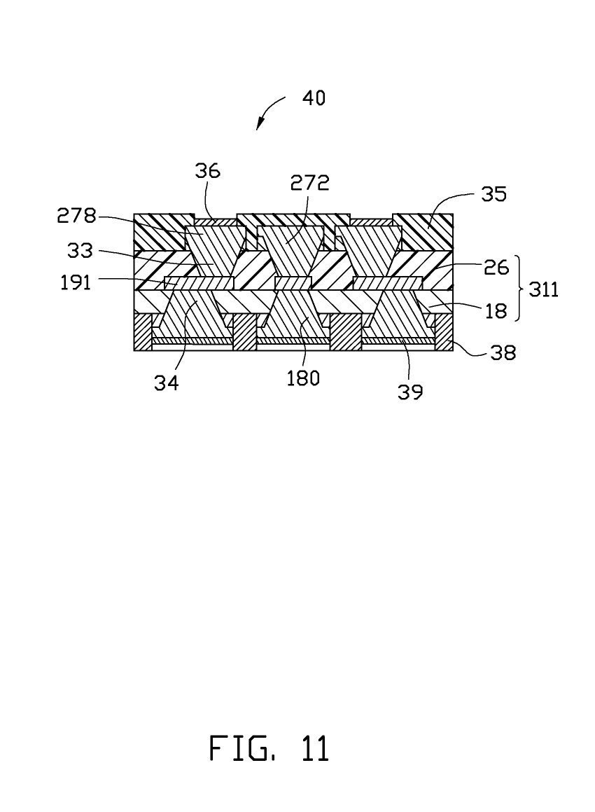

FIG. 11 shows step 8, a first solder mask 35 is formed on the outer wiring layer 272, and a second solder mask 38 is formed on the second adhesive sheet 18. The first solder mask 35 covers a portion of the fifth adhesive sheet 26 exposed from the outer wiring layer 272 and a portion of the outer wiring layer 272. The other portion of the outer wiring layer 272 exposed from the first solder mask 35 serves as a plurality of contact pads 278, and a first protection layer 36 is formed on each contact pad 278. The second solder mask 38 covers a portion of the second adhesive sheet 18 exposed from the conductive connection points 180, such that the conductive connection points 180 are exposed outside, and a second protection layer 39 is formed on each conductive connection point 180. A chip packaging substrate 40 is thus obtained, and the fifth adhesive sheet 26 and the second adhesive sheet 18 cooperatively constitute a dielectric layer 311 of the chip packaging substrate 40.

The first protection layer 36 and the second protection layer 39 may be gold layers or organic solderability preservatives (OSPs).

Referring to FIG. 11, the chip packaging substrate 40 includes a dielectric layer 311, the first inner wiring layer 191 embedded in the dielectric layer 311, the outer wiring layer 278, the conductive connection points 180, a first solder mask 35, and a second solder mask 38. The outer wiring layer 278 is formed at one side of the dielectric layer 311, and is electrically connected to the inner wiring layer 191 through the first conductive vias 33 in the dielectric layer 311. The conductive connection points 180 are formed at the other side of the dielectric layer 311, and are electrically connected to the inner wiring layer 191 through the second conductive vias 34 in the dielectric layer 311. The first solder mask 35 is formed on the outer wiring layer 272, and the second solder mask 38 is formed on the second adhesive sheet 18. The first solder mask 35 covers the portion of the fifth adhesive sheet 26 exposed from the outer wiring layer 272 and the portion of the outer wiring layer 272. The other portion of the outer wiring layer 272 exposed from the first solder mask 35 serves as the contact pads 278, and the first protection layer 36 is formed on each contact pad 278. The second solder mask 38 covers the portion of the second adhesive sheet 18 exposed from the conductive connection points 180, such that the conductive connection points 180 are exposed outside, and each of the second protection layer 39 is formed on one corresponding conductive connection point 180.

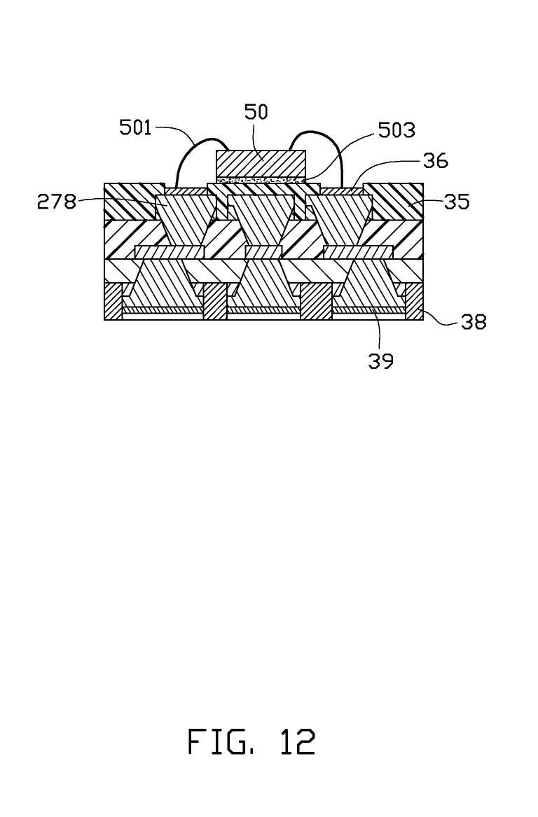

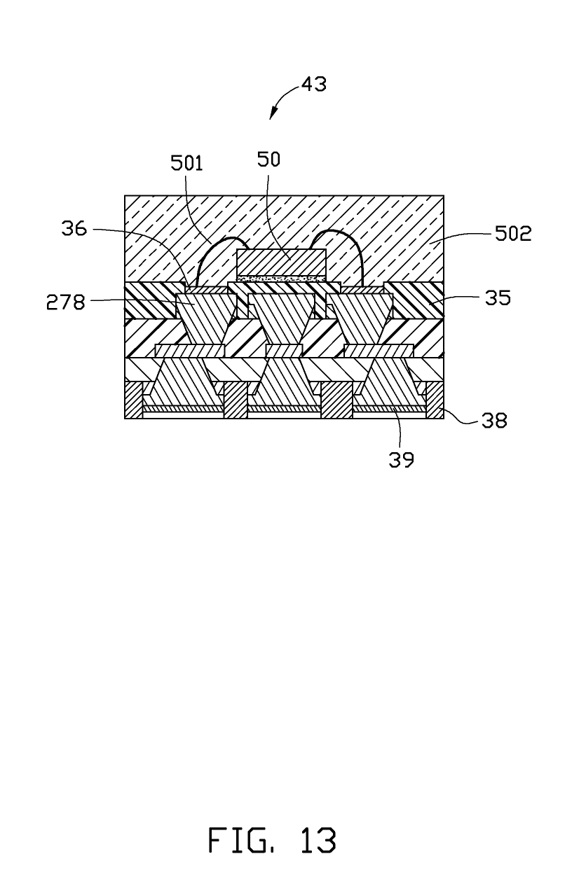

FIGS. 12 and 13 show that in step 9, a chip 50 is packaged on the chip packaging substrate 40, thereby obtaining a packaging structure 43.

A method for packaging the chip 50 on the chip packaging substrate 40 includes the following steps. First, referring to FIG. 12, the chip 50 is adhered onto the chip packaging substrate 40. In the present embodiment, the chip 50 is adhered onto the first solder mask 35. When adhering the chip 50 onto the chip packaging substrate 40, there is an adhesive layer 503 sandwiched between the first solder mask 35 and the chip 50, thereby making the chip 50 steadily adhere onto the first solder mask 35. Second, each electrode pad of the chip 50 is connected to a contact pad 278 through a bonding wire 501 by using a wire bonding technology. Finally, referring to FIG. 13, a packaging material 502 is formed on the chip 50 and the chip packaging substrate 40, such that the chip 50, the bonding wires 501, the first solder mask 35 of the chip packaging substrate 40, and the contact pads 278 are totally covered by the packaging material 502. The packaging material 502 may be a thermosetting resin, polyimide resin, epoxy resin, or silicone resin, for example.

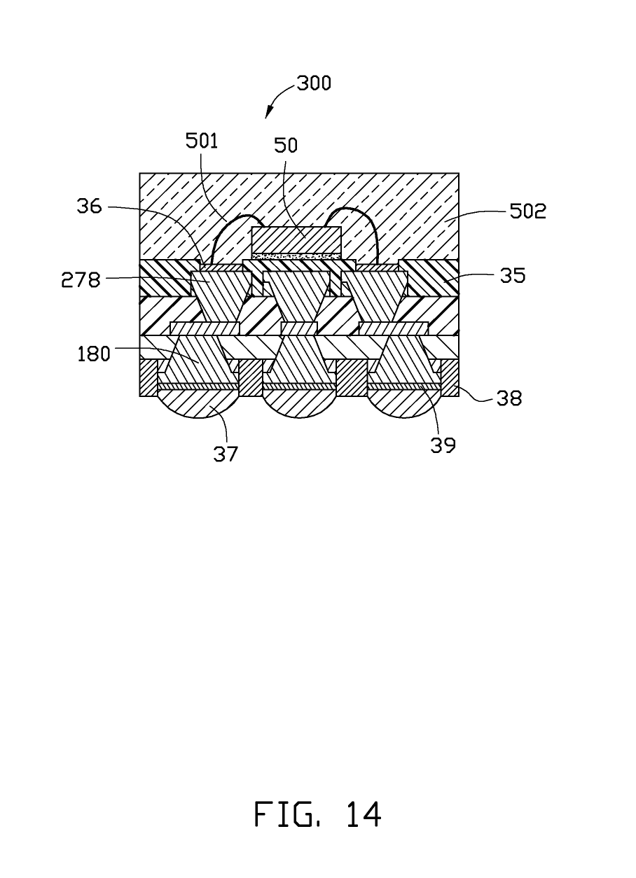

FIG. 14 shows that in step 10, a solder ball 37 is formed on one corresponding conductive connection point 180, thereby obtaining a chip packaging structure 300.

In alternative embodiments, the chip 50 may be packaged on the chip packaging substrate 40 by a flip chip technology. In such case, the first protection layer 36 may be omitted.

In actual production, the first substrate 31 in step 6 usually includes a plurality of substrate units connected to each other, and the second substrate 32 also includes a plurality of substrate units. From step 7 to step 10, the substrate units of the first substrate 31 are converted into a plurality of chip packaging substrates 40, the chip packaging substrates 40 are converted into a plurality of chip packaging structures 300, and the chip packaging structures 300 are separated from each other by cutting. In the present embodiment, in order to describe more easily, it only draws one substrate unit in each of the first substrate 31 and the second substrate 32.

Referring to FIG. 14, the chip packaging structure 300 includes the chip packaging substrate 40, the chip 50, the packaging material 502, and the solder balls 37. The chip 50 is adhered onto the first solder mask 35 through the adhesive layer 503. The chip 50 is electrically connected to the contact pads 278 through the bonding wires 501. The bonding wires 501 are gold wires. The packaging material 502 covers the bonding wires 501, the chip 50, the solder mask 35, and the contact pads 278. Each solder ball 37 is soldered on one corresponding conductive connection point 180.

In the present embodiment, there is no core layer in the chip packaging substrate 40, so a thickness of the chip packaging substrate 40 is reduced, and a thickness of the chip packaging structure 300 having the chip packaging substrate 40 is also reduced.

While certain embodiments have been described and exemplified above, various other embodiments will be apparent from the foregoing disclosure to those skilled in the art. The disclosure is not limited to the particular embodiments described and exemplified but is capable of considerable variation and modification without departing from the scope and spirit of the appended claims.

What is claimed is:

1. A method for manufacturing a chip packaging substrate, comprising:
providing a supporting substrate, a first adhesive sheet, a first copper foil, a second adhesive sheet, a second copper foil, a third adhesive sheet, a third copper foil, a fourth adhesive sheet, and a fourth copper foil;
stacking and laminating the second copper foil, the second adhesive sheet, the first copper foil, the first adhesive sheet, the supporting substrate, the third adhesive sheet, the third copper foil, the fourth adhesive sheet, and the fourth copper foil in the described order;
patterning the second copper foil into a first inner wiring layer, and patterning the fourth copper foil into a second inner wiring layer;
laminating a fifth adhesive sheet and a fifth copper foil onto the first inner wiring layer, and laminating a sixth adhesive sheet and a sixth copper foil onto the second inner wiring layer, such that the fifth adhesive sheet is sandwiched between the first inner wiring layer and the fifth copper foil, and the sixth adhesive sheet is sandwiched between the second inner wiring layer and the sixth copper foil;
removing the supporting substrate, the first adhesive sheet, and the third adhesive sheet from the first copper foil and the third copper foil, thereby obtaining a first substrate, the first substrate comprising the second adhesive sheet, the fifth adhesive sheet, the first inner wiring layer, the first copper foil, and the fifth copper foil, the second adhesive and the fifth adhesive sheet cooperatively constituting a dielectric layer of the first substrate, the first inner wiring layer being embedded in the dielectric layer, the first copper foil and the fifth copper foil being at two opposite sides of the dielectric layer; and
forming an outer wiring layer at a side of the first copper foil or a side of the fifth copper foil, forming a plurality of conductive connection points at the side of the fifth copper foil or the side of the first copper foil, such that the outer wiring layer and the conductive connection points are respectively located at two opposite sides of the dielectric layer, electrically connecting the outer wiring layer to the first inner wiring layer, and electrically connecting the conductive connection points to the first inner wiring layer, thereby obtaining a chip packaging substrate.

2. The method of claim 1, further comprising a step of forming a first solder mask on the outer wiring layer, the first solder mask partially covering the outer wiring layer, and a portion of the outer wiring layer exposed from the first solder mask serving as contact pads.

3. The method of claim 2, wherein after forming the first solder mask, the method further comprises a step of forming a first protection layer on each of the contact pads.

4. The method of claim 1, further comprising a step of forming a second solder mask on a side of the conductive connection points, the conductive connection points being exposed from the second solder mask.

5. The method of claim 1, wherein a method of manufacturing the supporting substrate comprises:
providing a first base, a connection sheet, and a second base, each of the first base and the second base being a double-sided copper-clad laminate;
stacking the first base, the connection sheet, and the second base one on another, such that the connection sheet is sandwiched between the first base and the second base; and
laminating the first base, the connection sheet, and the second base at one time to obtain the supporting substrate.

6. The method of claim 5, wherein in the step of stacking the first base, the connection sheet, and the second base one on another, a first copper sheet is arranged between the first base and the connection sheet, and a second copper sheet is arranged between the second base and the connection sheet, a cross-section of the first base, a cross-section of the second base, and a cross-section of the second base are identical to each other, a cross-section of the first copper sheet and a cross-section of the second copper sheet are identical to each other, the cross-section of the first copper sheet is smaller than the cross-section of the connection sheet, the connection sheet comprises a central area and a peripheral area surrounding the central area, the cross-section of the first copper sheet is slightly larger than the central area; in the step of laminating the first base, the connection sheet, and the second base at one time, the first copper sheet is laminated between the connection sheet and the first base, and the second copper sheet is laminated between the connection sheet and the second base.

7. The method of claim 1, wherein forming an outer wiring layer at a side of the first copper foil or a side of the fifth copper foil, forming a plurality of conductive connection points at the side of the fifth copper foil or the side of the first copper foil, such that the outer wiring layer and the conductive connection points are respectively located at two opposite sides of the first inner wiring layer, electrically connecting the outer wiring layer to the first inner wiring layer, and electrically connecting the conductive connection points to the first inner wiring layer, comprises:
defining a plurality of first blind vias in the fifth adhesive sheet and the fifth copper foil by laser ablation, and defining a plurality of second blind vias in the first copper foil and the first adhesive sheet, such that one side of the first inner wiring layer is exposed from the first blind vias, and the other side of the first inner wiring layer is exposed from the second blind vias;
panel plating copper on the first base with the first blind vias and the second blind vias, thereby forming a first plating copper layer in the first blind vias and the fifth copper foil, and forming a second plating copper layer in the second blind vias and the first copper foil; and
patterning the fifth copper foil and the first plating copper layer into the outer wiring layer, and the first copper foil and the second plating copper layer into the conductive connection points using an image transfer process and a etching process.

8. A chip packaging substrate, comprising:
a dielectric layer;
a first inner wiring layer embedded in the dielectric layer;
an outer wiring layer formed at one side of the dielectric layer, the outer wiring layer being electrically connected to the first inner wiring layer through a plurality of first conductive vias in the dielectric layer; and
a plurality of conductive connection points formed at the other side of the dielectric layer, and electrically connected to the first inner wiring layer through a plurality of second conductive vias in the dielectric layer.

9. The chip packaging substrate of claim 8, further comprising a first solder mask on the outer wiring layer, the first solder mask, the first solder mask covering a portion of the fifth adhesive sheet exposed from the outer wiring layer and a portion of the outer wiring layer, the other portion of the outer wiring layer exposed from the first solder mask configured for serving as a plurality of contact pads.

10. The chip packaging substrate of claim 9, further comprising a plurality of first protection layers, each of the first protection layers being formed on one corresponding contact pad.

11. The chip packaging substrate of claim 8, further comprising a second solder mask on a side of the conductive connection points, the conductive connection points being exposed from the second solder mask.

12. The chip packaging substrate of claim 11, further comprising a plurality of second protection layers, each of the second protection layers being formed on one corresponding conductive connection point.

13. A chip packaging structure, comprising:
a chip packaging substrate, comprising:
a dielectric layer;
a first inner wiring layer embedded in the dielectric layer;
an outer wiring layer formed at one side of the dielectric layer, the outer wiring layer being electrically connected to the first inner wiring layer through a plurality of first conductive vias in the dielectric layer; and
a plurality of conductive connection points formed at the other side of the dielectric layer, and electrically connected to the first inner wiring layer through a plurality of second conductive vias in the dielectric layer; and
a chip, the chip being packaged at a side of the outer wiring layer of the chip packaging substrate, and being electrically connected to the contact pads.

14. The chip packaging structure of claim 13, wherein the chip packaging substrate further comprises a first solder mask on the outer wiring layer, the first solder mask covers a portion of the fifth adhesive sheet exposed from the outer wiring layer and a portion of the outer wiring layer, the other portion of the outer wiring layer exposed from the first solder mask configured for serving as a plurality of contact pads.

15. The chip packaging structure of claim 14, the chip packaging substrate further comprises a plurality of first protection layers, each of the first protection layers is formed on one corresponding contact pad.

16. The chip packaging substrate of claim 13, wherein the chip packaging substrate further comprises a second solder mask on a side of the conductive connection points, the conductive connection points being exposed from the second solder mask.

17. The chip packaging substrate of claim 16, wherein the chip packaging substrate further comprises a plurality of second protection layers, each of the second protection layers is formed on one corresponding conductive connection point.
